(19) United States
(12) Patent Application Publication
(10) Pub. No.: US 2004/0212392 A1
(43) Pub. Date: Oct. 28, 2004

(54) Measuring device and measuring method for electric motors

(75) Inventors: Hubert Hauser, Balgheim (DE); Karl Gerhard Weiss, (US); Susanne Weiss, Munich (DE); Annette Sader, Berlin (DE); Guido Schmid, Triberg (DE)

Correspondence Address: LAW OFFICE OF BARRY R LIPSITZ, 755 MAIN STREET, MONROE, CT, 06468, US

(73) Assignee: Minebea Co., Ltd., Miyota-machi (JP)

(21) Appl. No.: 10/759,757

(22) Filed: Jan. 16, 2004

(30) Foreign Application Priority Data
Jan. 20, 2003 (DE) 103 02 531

(51) Int. Cl. G01R 31/34

(52) U.S. Cl. 324/772

(57) ABSTRACT

In order to provide a measuring device for electric motors, in particular spindle motors, comprising a motor mount, in which the electric motor to be tested can be positioned on the stator side for the measurement, and a first runout measuring device, which has at least a first runout sensor and with which a runout in a first direction can be sensed on a rotor of the electric motor held in the motor mount, which device allows the most efficient possible measuring of individual parameters of an electric motor, it is proposed to provide a second runout measuring device which has at least a second runout sensor and with which a runout of the rotor in a second direction, extending transversely in relation to the first direction, can be measured at the same time as the runout in the first direction.

The present disclosure relates to the subject matter disclosed in German application No. 103 02 531.6 of Jan. 20, 2003, which is incorporated herein by reference in its entirety and for all purposes.

### BACKGROUND OF THE INVENTION

The invention relates to a measuring device and a measuring method for electric motors, in particular spindle motors, comprising a motor mount, in which the electric motor to be tested can be positioned on the stator side for the measurement, and a first runout measuring device, which has at least a first runout sensor and with which a runout in a first direction can be sensed on a rotor of the electric motor held in the motor mount.

In the case of the known measuring devices and measuring methods for electric motors, usually each individual parameter is measured in a separate device, with the result that the measuring of electric motors necessitates a large number of devices and is extremely time-consuming.

It is therefore an object of the invention to provide a measuring device and measuring method for electric motors which allow the most efficient possible measuring of individual parameters of an electric motor.

### SUMMARY OF THE INVENTION

This object is achieved according to the invention in the case of a measuring device of the type described at the beginning by providing a runout measuring device which has at least a second runout sensor and with which a runout of the rotor in a second direction, extending transversely in relation to the first direction, can be measured at the same time as the runout in the first direction.

To be regarded as the advantage of this solution is that it provides the possibility of simultaneously measuring the runout of the rotor in two directions extending transversely in relation to each other and consequently of carrying out the runout measurement more efficiently.

To be regarded as a further advantage of the solution according to the invention is that the precision of the runout measurement is also improved in this way, since for this purpose the electric motor only has to be set up once in a motor mount, and consequently the positioning errors of the motor mount affect the precision of the runout measurements in both directions in the same way, and consequently no additional positioning errors can be caused by the electric motor being set up again for a further runout measurement.

The runout sensors can in principle operate in such a way that they are in contact with the rotor.

However, in particular to allow the precision of the runout measurement to be improved and also to operate with higher rotational speeds, it is particularly suitable if the first runout sensor and the second runout sensor are contactless sensors.

Such contactless sensors could in principle be inductive sensors. It is particularly advantageous if the runout sensors are capacitive sensors.

In particular when capacitive sensors are used, there is the problem that they produce charge accumulations and charge displacements, so that there is the risk of the measurement with one of the runout sensors influencing the measurement of the other runout sensor.

For this reason, it is preferably provided that a carrier frequency of the first runout sensor and a carrier frequency of the second runout sensor operate with a phase shift, so that as a result mutual influencing of the runout sensors can be suppressed. It is particularly advantageous if the carrier frequency of the first runout sensor and the carrier frequency of the second runout sensor operate approximately in phase opposition, in order to achieve substantial suppression of the effect of the runout sensors on each other.

Since the runout sensors should sense the respective spacing from the rotor as precisely as possible, in particular in the range of micrometers, exact positioning of the runout sensors in relation to the rotor is required for carrying out the runout measurement. For this reason, it is preferably provided that the first runout sensor is mounted on a first sensor advancing unit and can be advanced by this toward the rotor in the first direction.

In order to achieve precise positioning of the first runout sensor, it is particularly advantageous if a controller which uses the first runout sensor as a spacing sensor during the advancement toward the rotor is provided for activating the first sensor advancing unit, so that the runout sensor itself can be used for the purpose of positioning it in an optimum spacing range for the later runout measurement.

The controller is preferably used to advance the first runout sensor with the rotor rotating, in order to allow the optimum position of the runout sensor according to the runout occurring to be fixed.

In addition, an advantageous solution provides that the second runout sensor is mounted on a second sensor advancing unit and can be advanced by this toward the rotor in the second direction.

It is preferably provided in this case that a second controller which uses the second runout sensor as a spacing sensor during the advancement toward the rotor is provided for activating the second sensor advancing unit, so that it is also possible when the second runout sensor is being positioned for it to be used itself for the purpose of achieving an optimum spacing from the rotor for the runout measurement.

In particular, the controller is used to advance the second runout sensor with the rotor rotating, in order also in the case of the second runout sensor to allow its optimum position according to the runout occurring to be fixed.

To be able to carry out runout measurements that are as precise as possible, it is provided that the respective runout measuring device determines for every individual revolution from a multiplicity of revolutions of the rotor in the same rotational positions of the rotor in each case a measured value associated with each individual rotational position for the runout in this rotational position.

In particular, the measured value for the runout in the respective rotational position corresponds to a spacing between the rotor and the respective runout sensor, which is obtained for example from a spacing between the surface of the rotor used for the measurement and the sensor surface of the runout sensor.

In order to ensure that, for each individual revolution from a multiplicity of revolutions, in each case a runout measurement is always performed in the same rotational positions of the rotor, it is preferably provided that the ascertainment of the individual rotational positions is performed by synchronization of a trigger signal for the runout measurement by the respective runout measuring device with the rotational movement of the rotor.

Such a synchronization with the rotational movement of the rotor could take place for example by a marking of the rotor being detected for the synchronization.

However, this would have the consequence that the rotor would have to be provided with a marking for the runout measurement in the case of the respective electric motor in the measuring device.

For this reason, it is preferably provided that the synchronization of the runout measurement with the rotational movement of the rotor is performed by the respective runout measuring device without any markings.

Such a marking-free synchronization of the runout measurement with the rotational movement is performed in the case of a preferred embodiment of the solution according to the invention by sensing the variation over time of the voltage at an electrical terminal of the electric motor with a voltage sensing circuit.

For example, the voltage sensing circuit could detect amplitude maxima of the voltage. It is particularly advantageous if the voltage sensing circuit senses zero crossings of the voltage at the one electrical terminal of the electric motor.

Since the number of zero crossings of the voltage also depends on the number of poles of the electric motor, it is preferably provided that, after sensing a zero crossing, the voltage sensing circuit senses the zero crossing corresponding to the number of poles of the electric motor and indicating the beginning of the next-following revolution, so that there is the possibility of unequivocally detecting the beginning of the next revolution of the rotor and correspondingly synchronizing the runout measurement.

In order then to be able to fix the individual rotational positions of the rotor synchronously in relation to the respective revolution, it is preferably provided that the sensing of the zero crossings respectively indicating a new revolution is used in a phase-locked manner to derive a corresponding trigger signal, by which a subdivision of each revolution of the rotor takes place into a defined number of rotational positions for which a measured value of the respective runout sensor is to be sensed.

For an evaluation of the runout measurement, in particular with regard to a differentiation between a repeatable runout and a non-repeatable runout, it is particularly advantageous to provide a measured-value acquisition, which acquires the measured values for each individual rotational position that are measured by the respective runout sensor.

The determination of the repeatable runout could be performed for example by the measured values associated with each individual rotational position being statistically evaluated.

A method that is particularly advantageous with regard to feasibility provides that the measured-value acquisition forms a mean value from the measured values of the respective runout sensor that are associated with each individual rotational position.

When such a mean value is formed, the repeatable runout can be ascertained in the simplest case by the measured-value acquisition determining the maximum difference between the mean values of all the rotational positions of a revolution of the rotor.

When the mean values of the measured values are calculated, it is likewise suitable to determine the non-repeatable runout by calculating the deviations of the individual measured values from the mean value. For this reason, it is suitably provided that the measured-value acquisition determines the maximum deviation of the measured values from the mean value for each rotational position.

The non-repeatable runout can then be advantageously ascertained by the measured-value acquisition determining the maximum difference between the maximum deviations ascertained in respect of all the rotational positions of a revolution of the rotor.

A further advantageous procedure provides that, with the runout measuring device, the time-dependently ascertained measured values for the runout are Fourier-transformed and that a frequency spectrum resulting from this is evaluated.

The evaluation of a frequency spectrum ascertained from the runout measurement by Fourier transformation provides the possibility of obtaining additional findings concerning instances of damage that are possibly present, in particular in the mounting of the rotor.

It is particularly advantageous in this case if an analysis of the frequency spectrum corresponding to all the speed-harmonic frequencies is performed. These frequencies may be additional interference frequencies, which can be detected by the analysis, or else amplitudes of higher harmonics. In any event, it is possible with such an analysis to detect bearing problems in the broadest sense, for example bearing damage or states of mechanical stress of the bearings and, if appropriate with regard to their relevance for the electric motor, quantitatively assess them by ascertaining the amplitude in the case of the respective frequency for their relevance with regard to the running properties and service life of the electric motor.

As an alternative or in addition to the embodiment described above of the solution according to the invention, a further advantageous embodiment provides that the measuring device has a voltage induction measuring device, which measures a voltage induced in the non-energized windings of the electric motor with the rotor running freely.

To be regarded as the advantage of this solution according to the invention is that no external drive of the rotor is required to measure the voltage induced in the windings. Rather, it is possible with the measuring device according to the invention to measure the induced voltage with the rotor running freely, it being assumed with the rotor running freely that the rotor steadily reduces its rotational speed on account of no drive being provided.

In principle, it would also be conceivable to drive the rotor by an external motor and then to measure the induced voltage in the windings with the rotor freely slowing down.

Since, however, in the case of the measuring device according to the invention, the motor must in any case be connected by its winding terminals, it is preferably provided that the voltage induction measuring device is connected to the windings via a switching unit and that the switching unit can be switched in such a way that the induced voltage can be measured directly after energizing of the electric motor is switched off.

This dispenses with an additional drive for the measurement of the induced voltage and, moreover, the measurement of the induced voltage is possible, for example directly following the runout measurement, so that the measurement of the induced voltage is extremely economical in terms of time, to be specific it can be carried out in the slowing-down phase of the electric motor that is required in any case after the runout measurement.

To be able also in the slowing-down phase of the rotor to ascertain the induced voltage for a specific nominal rotational speed, it is preferably provided that, after the electric motor is operated at the nominal rotational speed with the rotor freely slowing down, the measuring device ascertains by means of a computer the amplitude maxima and zero crossings of the induced voltage influenced by reducing the rotational speed of the rotor, and adapts a theoretical profile of the induced voltage to these values and uses this adapted theoretical profile to ascertain the amplitude values of the induced voltage and zero crossings of the induced voltage for an unbraked rotation of the rotor at the nominal rotational speed.

On the basis of this computing operation, it is consequently possible to ascertain the voltage induced in the windings for a specific nominal rotational speed, without having to drive the rotor at the nominal rotational speed during the ascertainment.

This can be carried out particularly advantageously if the computer senses the variation over time of the amplitude of the induced voltage by means of an envelope curve adapted to amplitude maxima of the induced voltage.

To be able to determine further parameters of the electric motor by means of the measuring device according to the invention, it is preferably provided that the measuring device has an inductance measuring device and an external stepping motor for driving the rotor, that the stepping motor can be used to rotate the rotor into individual rotational positions and that the inductance measuring device can be connected to the winding terminals of the electric motor, so that a measured value of the inductance of windings of the electric motor can be sensed in respect of each rotational position.

Furthermore, for the determination of further parameters, it is provided that the measuring device has a stray flux measuring device comprising a stray flux sensor and that, in a measuring position with the rotor slowing down and without energizing of the same, the stray flux sensor measures a minimum value and a maximum value of the magnetic stray flux at a specific location of the rotor.

Finally, a further advantageous embodiment of the measuring device according to the invention provides that it comprises a winding resistance measuring device, which measures the resistance of the windings of the stationary electric motor.

In addition, the invention relates to a measuring method for electric motors, in particular spindle motors, in which the electric motor to be tested is positioned for the measurement on the stator side in a motor mount, and a first runout measuring device, having a first runout sensor, is used to sense a runout of a rotor of the electric motor in a first direction and, furthermore, according to the invention a second runout measuring device, having a second runout sensor, is used to sense a runout of the rotor in a second direction, extending transversely in relation to the first direction, at the same time as the runout in the first direction.

To be regarded as the advantage of the measuring method according to the invention is that it provides the possibility of carrying out runout measurements in two directions extending transversely in relation to each other as efficiently as possible in terms of time and with high precision, since the performance of the measurement can be carried out in a single setup of the motor.

Further advantageous aspects of the measuring method according to the invention and further embodiments of the measuring method according to the invention are the subject of the further method claims.

Furthermore, further features and advantages of the invention are the subject of the description which follows and of the graphic representation of an exemplary embodiment.

### BRIEF DESCRIPTION OF THE DRAWINGS

FIG. 1 shows a cross-section through an exemplary embodiment of an electric motor to be measured with a measuring device according to the invention and a measuring method according to the invention, in this case a spindle motor;

FIG. 2 shows a side view of an exemplary embodiment of a device of a measuring unit according to the invention;

FIG. 3 shows a representation of the device according to FIG. 2 together with a schematic block diagram of the associated measuring evaluation of the measuring device according to the invention;

FIG. 4 shows a schematic representation of a stator of the electric motor with windings that is to be measured and a detailed wiring diagram;

FIG. 5 shows a schematic representation for the ascertainment of an output signal synchronous with the rotational speed of the electric motor;

FIG. 6 shows a schematic representation for the acquisition of measured values in the example of measured values for the radial runout;

FIG. 7 shows a schematic representation for the ascertainment of mean values for determining a repeatable radial runout and an additional representation of measured values of the radial runout, which provide a measure of a non-repeatable radial runout;

FIG. 8 shows a schematic representation of a frequency spectrum, obtained from a Fourier transformation of measured values of the runout measurement;

FIG. 9 shows a schematic representation of the variation over time of a voltage induced in windings of an electric motor with a rotor freely slowing down, and

FIG. 10 shows a schematic representation of a computed profile of a voltage induced in windings of the electric motor for a nominal rotational speed.

### DETAILED DESCRIPTION OF THE INVENTION

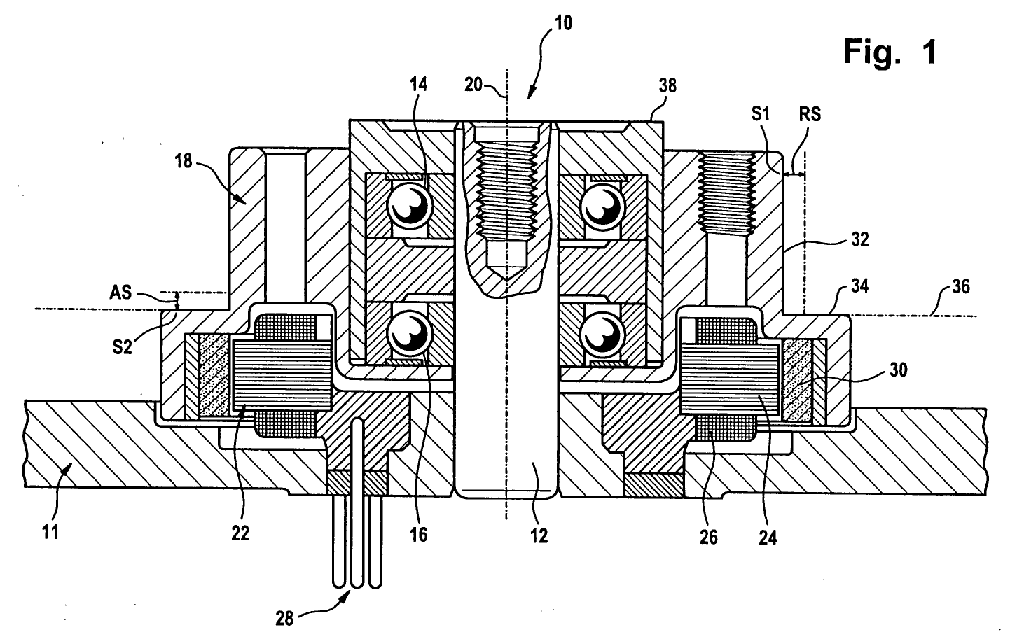

An electric motor 10, provided by way of example for the measurement with the device according to the invention and the method according to the invention, is a so-called spindle motor (represented in FIG. 1), which has a base plate 11, which carries a shaft 12 which is firmly connected to said base plate and on which a rotor 18 is mounted rotatably about an axis of rotation 20 by two bearings 14 and 16 disposed at a spacing from each other.

The rotor 18 is formed in a bell-like manner and engages over a stator 22, which is held on the base plate 11, likewise in a fixed manner, and has pole shoes 24 and windings 26 which surround the latter and can be energized via contact pins 28 led through the base plate 11.

Furthermore, the rotor 18 carries permanent magnets 30, which face the pole shoes 24 and are disposed on an inner side of the rotor.

The rotor 18 of such a spindle motor 10 usually serves the purpose of receiving hard disks, magnetic disks or similar elements on which information can be optically or magnetically recorded and driving them in a rotating manner, and has for this purpose an outer lateral surface 32, extending in a circular-cylindrical manner in relation to the axis of rotation 20, and a flange surface 34, which adjoins the lateral surface 32 and extends at a defined angle, preferably extends perpendicularly in relation to the lateral surface 32, for example parallel to a plane 36 which extends perpendicularly in relation to the axis of rotation 10. Furthermore, the rotor 18 has on a side opposite from the flange surface 34 an upper side 38.

Inaccuracies in the production of the shaft 12, the bearings 14 and 16 and the rotor 18 then have the overall effect on the rotor 18 rotating about the axis of rotation 20 of a so-called radial runout RS of the rotor 18, which is manifested by the rotating lateral surface 32 appearing to move radially in relation to the axis of rotation 20—as shown in an exaggerated way by the arrows in FIG. 1 —when a first location S1 of the rotor 18 that is fixed in relation to the base plate 11 is observed.

In addition, likewise due to inaccuracies in production, the rotor 18 has a so-called axial runout AS, which is manifested by the flange surface 34 that rotates with the rotor 18 appearing to move in a direction parallel to the axis of rotation 20 when a second location S2 that is fixed in relation to the base plate 11 is observed.

The radial runout RS and the axial runout AS of the rotor 18 then define a measure of the precision with which the rotor 18 is mounted and guided rotatably about the axis of rotation 20.

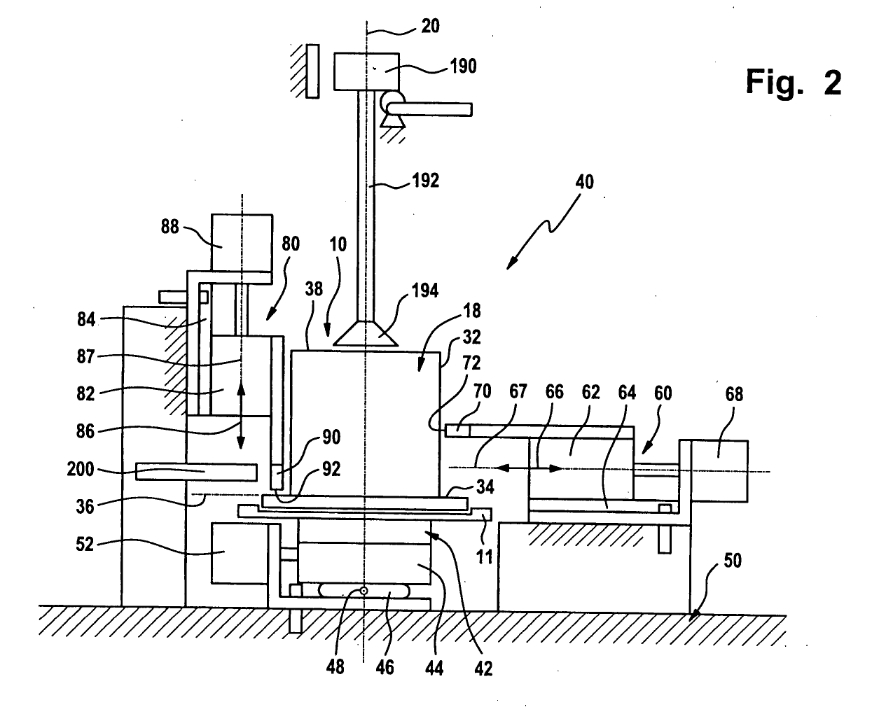

For determining the radial runout RS and the axial runout AS, a measuring device designated as a whole by 40 and represented in FIG. 2 is provided, having a motor mount 42 to which the base plate 11 of the spindle motor 10 can be fixed.

In this case, the motor mount 42 is preferably formed as a motor mount 42 receiving and securing the base plate 11 in a defined manner, in particular securing it in a controlled manner.

Furthermore, the motor mount 42 is preferably disposed on a carriage 44, which can be moved by means of a carriage guide 46 in a direction 48 which in FIG. 2 extends perpendicularly in relation to the plane of the drawing, the carriage 44 being able to move from a mounting position, in which the base plate 11 can be placed in the motor mount 42, into a measuring position, which is represented in FIG. 2.

In this measuring position, the carriage 44 is in a defined position in relation to a framework 50 of the measuring device 40 and consequently, on account of the precise positioning of the base plate 11 of the electric motor 10 in relation to the motor mount 42 and consequently with respect to the carriage 44, the rotor 18 of the electric motor 10 to be measured is also in a defined position, so that the axis of rotation 20 is also aligned and fixed in a defined manner in relation to the framework 50.

Preferably provided for moving and positioning the carriage 44 in relation to the framework 50 is an advancing drive 52, which is mounted on the framework 50, is coupled to the carriage 44 and by which the carriage 44 can be made to move and be positioned in a controlled manner in the direction 48.

Also provided on the framework 50 is a first sensor advancing unit, which is designated as a whole by 60 and has a first sensor carriage 62, which is guided on a first carriage guide 64 movably in relation to the framework 50 in a first direction 66 and can be moved and positioned in a controlled manner in the direction of the first direction 66 by means of a first advancing drive 68.

In this case, the first direction 66 preferably extends in a first plane 67, which extends transversely in relation to the axis of rotation 20 of the electric motor 10 in the measuring position. For example, it is provided that the first direction 66 intersects the axis of rotation 20, preferably at right angles.

Disposed on the first sensor carriage 62 is a first runout sensor 70, to be precise in such a way that a first sensor surface 72 of the same is facing the lateral surface 32 of the electric motor 10 in the measuring position.

Consequently, with the first sensor advancing unit 66 there is the possibility, when the electric motor 10 is moved into the measuring position, of moving the first runout sensor 70 with its first sensor surface 72 from a retracted position in the first direction 66 toward the rotor 18 to such an extent that the first sensor surface 72 of the first runout sensor 70 is in a detection position, represented in FIG. 2, close to the lateral surface 32.

Also provided on the framework 50 is a second sensor advancing unit 80, which has a second sensor carriage 82, which can be moved in a second direction 86 in relation to the framework 50 by means of a second carriage guide 84, a second advancing drive 88 being provided for this purpose, to allow the second sensor carriage 82 to be moved and positioned in a positionally controlled manner in the second direction 86.

The second direction 86 in this case extends in a second plane 87, which extends transversely in relation to the plane 36 in which the flange surface 34 lies.

The plane 87 preferably extends parallel to the axis of rotation 20 of the electric motor in the measuring position, and consequently in particular perpendicularly in relation to the plane 36.

Held on the second sensor carriage 82 is a second runout sensor 90, which can be advanced by the second sensor carriage 82 in the direction of the flange surface 34 of the electric motor 10 in the measuring position, until it is in a detection position represented in FIG. 2, in which the sensor surface 92 is at a suitable spacing from the flange surface 34.

Provided for carrying out the runout measurement of the rotor 18 is a central computer, which is designated as a whole by 100 and has a processor 102, a memory 104 and a data input/output unit 106. A rotational speed is specified by the central computer 100 by way of the data input/output unit 106 to a speed controller 108 for operating the electric motor 10, with the effect of activating a three-phase driver circuit 110, which for its part operates the electric motor 10 via a first switching unit 112, which can likewise be activated by the data input/output unit 106.

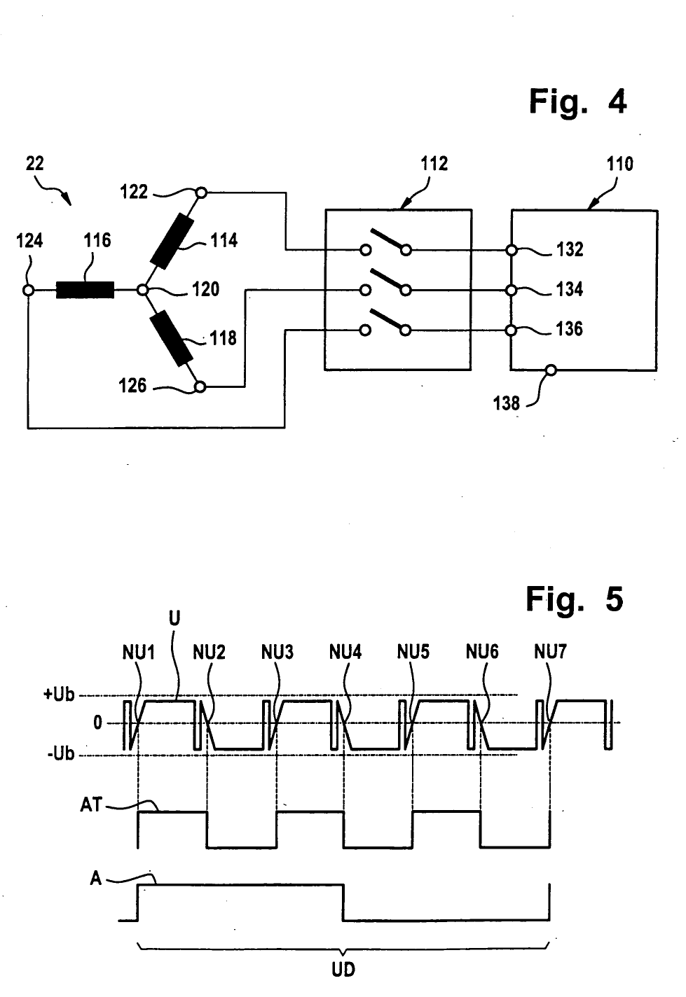

If in this case the electric motor 10 is a three-phase AC motor, then, as schematically represented in FIG. 4, the stator comprises three windings 114, 116, 118, which on the one hand are connected to one another at a star point 120 and on the other hand have three outer terminals 122, 124, 126, which are formed by the contact pins 28 and for their part are connected via the first switching unit 112 to the corresponding current terminals 132, 134 and 136 at the output of the three-phase driver circuit 110.

Furthermore, the three-phase driver circuit 110 is also provided with a further output 138, at which the voltage from one of the three current terminals 132, 134 and 136 is present when the first switching unit 112 is connected through, so that there is a connection between the current terminals 132, 134, 136 and the outer terminals 122, 124 and 126 of the windings 114, 116, 118.

The voltage U from one of the current terminals 132, 134 or 136 that is present at the output 138 is represented in FIG. 5 for the example of a six-pole electric motor 10, the voltage U that is respectively present changing between +Ub and −Ub. With this voltage U, the zero crossings NU of the same are sensed by a sampling circuit 140 and this sampling signal AT, represented in FIG. 5, is converted by dividing it by half the number of poles into an output signal A of the sampling circuit 140 which is exactly speed-synchronous with the rotation of the rotor 18 with regard to its variation over time and exactly represents one revolution UD of the rotor 18 about the axis of rotation 20.

That is to say that the output signal A is in proper phase with the rotation of the rotor 18, this output signal A being generated without additional marking of the rotor 18 simply by using the electric motor 10 as a sensor.

This output signal A is multiplied by two circuits operating in a phase-locked manner, or PLL circuits 142 and 144, for example in the PLL circuit 142 by a first factor and in the PLL circuit 144 by a second factor, and a trigger signal T generated by the PLL circuit 144 is used for the purpose of triggering measurements with the runout sensors 70, 90 at a respective triggering time TZ, each triggering time TZ corresponding to a rotational position of the rotor 18.

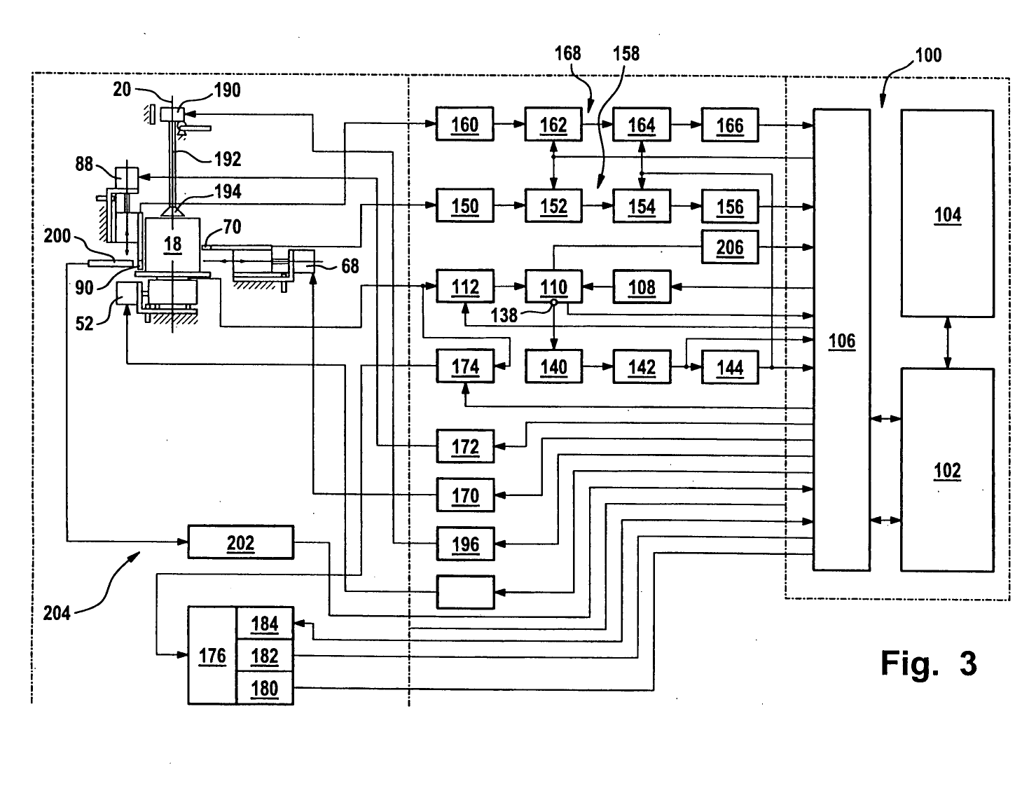

For runout measurement with the first runout sensor 70, the sensor has associated with it, as represented in FIG. 3, a first sensor amplifier 150, the output signal of which is further amplified by a first variable amplifier 152, then switched by a first switching stage 154 and amplified by a first output amplifier 156 to such an extent that it can be picked up by the data input/output unit 106 of the central computer 100. The first runout sensor 70, the first sensor amplifier 150, the first variable amplifier 152, the first switching stage 154 and the first output amplifier 156 altogether form a first runout measuring device 158.

Furthermore, the second runout sensor 90 has associated with it a second sensor amplifier 160, a second variable amplifier 162, a second switching stage 164 and a second output amplifier 166, which together with the second runout sensor 90 form a second runout measuring device 168 and operate in the same way as the corresponding components 150 to 156 which are associated with the first runout sensor 70.

The trigger signal T is in this case fed simultaneously to the first switching stage 154 and the second switching stage 164, so that a measured value M of the respective runout sensor 70, 90 that is present at the triggering time TZ of a positive trigger signal T is then amplified by the output amplifiers 156 and 166, respectively, fed to the data input/output unit 106 of the central computer 100 and stored by the latter.

Since the runout sensors 70, 90 are spacing sensors and consequently respectively ascertain the spacing of the lateral surface 32 from the first sensor surface 72 and the spacing of the flange surface 34 from the second sensor surface 92, at each individual triggering time TZ, and consequently in respect of each associated rotational position of the rotor 18, a corresponding spacing value sensed by the runout sensor 70 or 90 is ascertained as a measured value M, with the radial runout RS and the axial runout AS being obtained from the variation of the spacing values, measured by the runout sensors 70 and 90, per revolution UD.

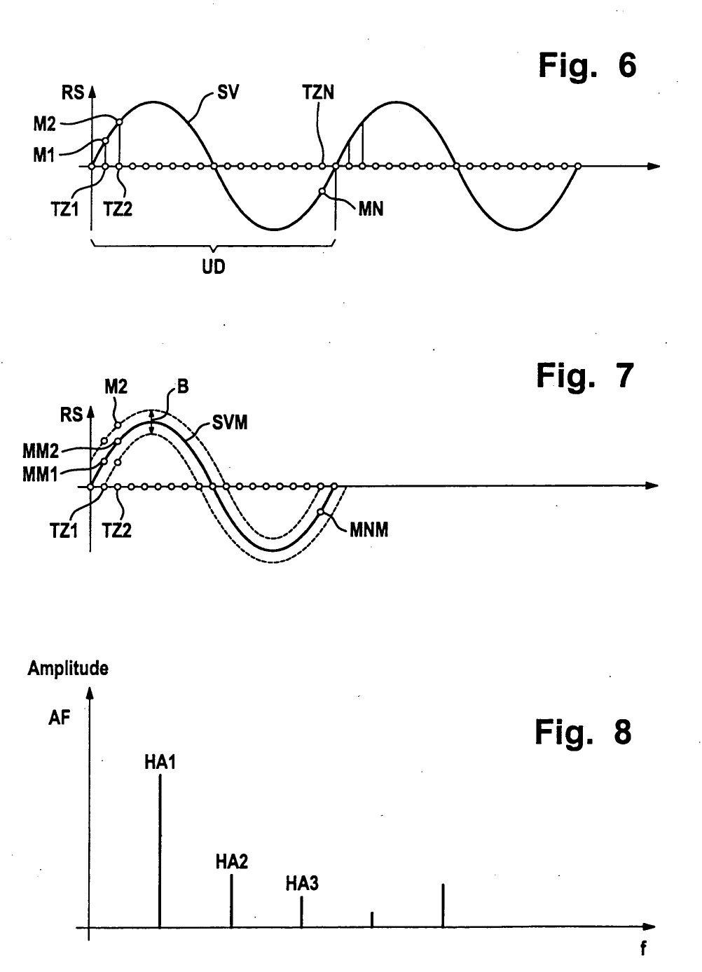

The measured values M1 to MN obtained in this way for example for the radial runout RS at each triggering time TZ1 to TZN during a revolution UD are schematically represented in FIG. 6. The sum of the measured values M1 to MN in this case produces for example a sinusoidal runout profile SV for the radial runout RS, although the runout profile SV could also be entirely different.

Since the triggering times TZ1 to TZN for each revolution UD correspond to a measurement at the same location of the rotor 18, that is to say with the same rotational position of the rotor 18, the measured values M1 to MN of many successive revolutions UD, referred to the individual revolutions, can be added together and averaged, so that a mean value MM1 . . . MMN can be determined for each individual rotational position from the multiplicity of measured values M1 . . . MN measured for this rotational position with the multiplicity of revolutions UD, and these mean values MM1 . . . MMN produce an averaged profile SVM, which is represented in FIG. 7 and represents a measure of the repeatable radial runout RRS, that is to say a measure of all the deviations which occur repeatedly with each revolution at exactly the same rotational angle. A cause of such a repeatable radial runout RRS, represented by the profile SVM, would be, for example, a deviation in the form of the lateral surface 32 from the exact circular-cylindrical form in relation to the axis of rotation 20.

The maximum-repeatable runout in this case represents the maximum difference between the mean values MM determined for one revolution and can be ascertained by the central computer 100 by determining the maximum difference between the mean values occurring during a revolution UD.

Recorded in addition to the profile SVM are the deviations of all the acquired measured values M from the profile SVM, which usually lead to a bandwidth B that follows the profile SVM and is a measure of the non-repeatable radial runout NRRS, which may be produced for example by the bearings 14, 16 if they are ball bearings and the balls for their part have geometrical deviations from the ideal form of a sphere, the geometrical deviations leading to random changes of the centering of the rotor 18 in relation to the axis of rotation 20 on account of the rotation of the balls, and consequently leading to a non-repeatable radial runout NRRS.

In addition, the non-repeatable runout NRRS can be determined by the central computer 100 determining for each individual rotational position the maximum deviation of the measured values M, acquired for this rotational position on the basis of the multiplicity of revolutions, from the mean value and then determining the maximum difference between the maximum deviations ascertained for all the rotational positions of a revolution of the rotor.

For the same reasons, a repeatable axial runout RAS and a non-repeatable axial runout NRAS are ascertained by the second runout sensor 90 on the basis of the same procedure.

The runout sensors 70, 90 are preferably capacitive sensors which, if they operate simultaneously, lead to charge displacements on the electrically conducting rotor 18. For this reason, to achieve simultaneous and synchronous measurement of the radial runout RS and the axial runout AS, the invention provides that the runout sensors 70, 90 are operated in such a way that they are phase-shifted by 180°, that is to say respectively operated with a carrier frequency, with one frequency being phase-shifted by 180° with respect to the other.

Furthermore, in order to be able to advance the runout sensors 70, 90 precisely toward the lateral surface 32 and the flange surface 34 by means of the sensor advancing units 60 and 80, respectively, for the runout measurement, it is preferably provided that the corresponding advancing drive 68 or 88 can be activated by the central computer 100 via an activating stage 170 or 172, respectively, the activating stages 170 and 172 being operated by the central computer 100 in such a way that, when the runout sensor 70 or 90 approaches the lateral surface 32 or the flange surface 34, it is used as a spacing sensor and consequently an optimum measuring distance can be set between the first runout sensor 70 and the lateral surface 32 and between the second runout sensor 90 and the flange surface 34 for measuring the spacing by means of the runout sensors 70 and 90 that are to be used later for the runout measurement.

In addition, the central computer 100 provides the possibility of carrying out a Fourier transformation of the measured values M acquired for the individual revolutions UD at the individual triggering times TZ and analyzing the amplitudes AF of the individual frequency components, in particular the amplitudes AF of the harmonics HA1 and all following amplitudes, represented as a frequency spectrum over the frequency f. In this case it can be assumed that the respective runout only produces frequency components which correspond to the first harmonic HA1 of the rotational speed and all higher harmonics HA2 and following harmonics represent interference frequencies, for example produced by the bearings 14 and 16. Analysis of the frequency components lying above the first harmonic HA1, in particular higher harmonics HA2 and following harmonics, represented in FIG. 8, provides the possibility of establishing if need be whether there are instances of appreciable damage in the bearings 14 and 16.

In addition, there is also the possibility of measuring the radial runout RS and the axial runout AS at different rotational speeds and establishing to what extent the amplitudes of the individual harmonics HA change.

To be able also to measure the electric motor 10 additionally with regard to further parameters without any appreciable additional expenditure of time, in particular in the non-energized state, provided in addition to the first switching unit 112 is a second switching unit 174, which is likewise connected to the winding terminals 122, 124 and 126 of the stator 22 and is constantly activated by the central computer 100 in such a way that it is connected through as an alternative to the first switching unit 112.

That is to say that the second switching unit 174 is always switched through whenever the first switching unit 112 is not switched through, and vice versa.

The second switching unit 174 can be used to connect to the winding terminals 122, 124 and 126 to a third switching unit 176, which is capable of optionally connecting either a voltage induction measuring device 180, an inductance measuring device 182 and a winding resistance measuring device 184 to the winding terminals 122, 124 and 126 via the second switching unit 174, the voltage induction measuring device 180, the inductance measuring device 182 and the winding resistance measuring device 184 respectively being connected for their part to the data input/output unit 106 of the central computer 100 and consequently being capable of transmitting the respective measured values to the central computer 100.

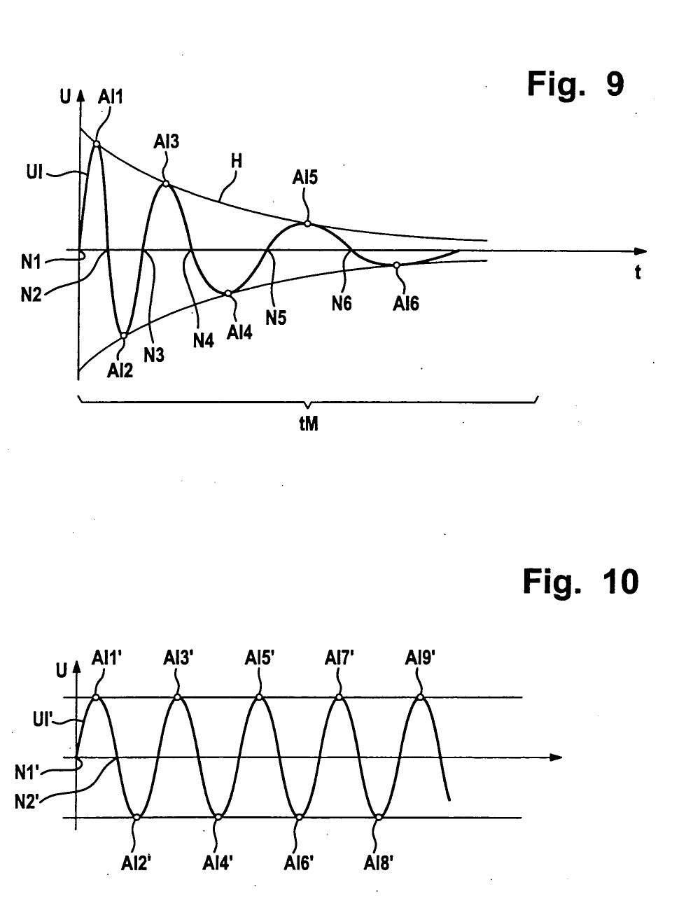

For this purpose, for example, the voltage UI induced in the windings 114, 116 and 118 of the stator 22 is sensed by means of the voltage induction measuring device 180 with the rotor 18 rotating freely, the variation over time of the voltage UI at one of the outer terminals 122, 124 126 being represented in FIG. 9. With the rotor 18 running freely, that is to say directly after the energizing of the windings 114, 116 and 118 has been switched off, the voltage UI in this case drops very quickly with regard to its amplitude AI, and furthermore the frequency changes very quickly, since the rotational speed of the rotor 18 decreases very rapidly, in particular in the case of a rotor 18 with a small mass, on account of the friction in the bearings 14, 16. The voltage actually induced in the individual windings 114, 116 and 118 in the case of a specific nominal rotational speed cannot be ascertained directly from the profile of the voltage UI schematically sketched in FIG. 9, on account of the rapid drop in the amplitude AI and the rapid drop in the rotational speed, which leads to rapidly increasing intervals of zero crossings N1, N2, . . . of the voltage UI. For this reason, the successive amplitude values AI1, AI2, AI3, AI4, etc. and the successive zero crossings N1, N2, N3, N4, etc. are ascertained exactly over as long a measuring period tM as possible, and then an envelope curve H is matched to these values in the central computer 100 and used for ascertaining in a way that takes into account the relationship between the rotational speed of the rotor 18, the change of the rotational speed of the rotor 18 on account of its braking and the voltage UI induced thereby in the windings 114, 116 and 118, how the variation of the induced voltage UI′ would be without braking of the rotor, as represented in FIG. 10, so that the zero crossings N1′, etc. and the values AI1′, etc. for the voltage UI′ without braking of the rotor 18 are obtained and then used for ascertaining the voltage UI′ induced in the windings 114, 116 and 118 for the case of a rotor 18 freely running at a constant rotational speed.

The inductance measuring device 182, on the other hand, measures the inductance with the rotor 18 at a standstill, the rotor 18 having to be brought into the individual angular positions over a full revolution for this purpose, to allow the inductance of the windings 114, 116 and 118 in the individual angular steps to be measured.

Provided for this reason is a stepping motor 190 with a drive shaft 192, which extends coaxially in relation to the axis of rotation 20 of the electric motor 10 in the measuring position and has at its end facing the rotor 18 a coupling element 194, for example a bell body of soft-elastic material, the entire unit comprising the stepping motor 190, the drive shaft 192 and the coupling element 194 being able to be moved toward the rotor 18 of the electric motor 10 in the measuring position for coupling the stepping motor to said rotor, so that the coupling element 194 can be brought into contact with the upper side 38 of the rotor 18 in order to drive the latter.

As represented in FIG. 3, the stepping motor 190 can in this case be activated by the central computer 100 in individual angle increments by means of an activating stage 196, so that the central computer 100 on the one hand can turn the rotor 18 into individual angular positions by means of the stepping motor 190 and on the other hand can determine the individual inductance of the windings 114, 116 and 118 by means of the inductance measuring device 182 and can record the individual rotational positions associated therewith.

In addition, the winding resistance measuring device 184 also additionally provides the possibility of determining by means of the central computer 100 the electrical resistance of the individual windings 114, 116 and 118 with the rotor 18 at a standstill, with no need for this to take place angle-dependently.

For measuring the stray flux of the electric motor 10, also held on the framework 50 is a stray flux sensor 200, which is connected to a stray flux sensing device 202, in order to measure the stray flux of the rotor 18.

For this purpose, the rotor 18 is driven in a rotating manner about the axis of rotation 20 and then, during idling, that is to say with the stator 22 rotating but not energized, the stray flux of the rotor 18 at a specific location is ascertained with regard to its minimum value and its maximum value by means of the stray flux sensor 200 with the stray flux sensing device 202, which represents a stray flux measuring device 204.

These minimum and maximum values ascertained by the stray flux measuring device 204 are likewise transmitted to the data input/output unit 106 and then stored in the central computer 100 for the respective electric motor 10.

Furthermore, also provided is a current measuring device 206, by which the current fed by the three-phase driver circuit 110 to the windings 112, 114, 116 can be sensed and transmitted to the central computer 100.

1. Measuring device for electric motors, in particular spindle motors, comprising a motor mount, in which the electric motor to be tested can be positioned on the stator side for the measurement, and a first runout measuring device, which has at least a first runout sensor and with which a runout in a first direction can be sensed on a rotor of the electric motor held in the motor mount, a second runout measuring device which has at least a second runout sensor and with which a runout of the rotor in a second direction, extending transversely in relation to the first direction, can be measured at the same time as the runout in the first direction.

2. Measuring device according to claim 1, wherein the first runout sensor and the second runout sensor are contactless sensors.

3. Measuring device according to claim 2, wherein the first runout sensor and the second runout sensor are capacitive sensors.

4. Measuring device according to claim 3, wherein a carrier frequency of the first runout sensor and a carrier frequency of the second runout sensor operate with a phase shift.

5. Measuring device according to claim 4, wherein the carrier frequency of the first runout sensor and the carrier frequency of the second runout sensor operate approximately in phase opposition.

6. Measuring device according to claim 1, wherein the first runout sensor is mounted on a first sensor advancing unit and can be advanced by this toward the rotor in the first direction.

7. Measuring device according to claim 6, wherein a controller which uses the first runout sensor as a spacing sensor during the advancement of the same toward the rotor is provided for activating the first sensor advancing unit.

8. Measuring device according to claim 7, wherein the controller advances the first runout sensor with the rotor rotating.

9. Measuring device according to claim 1, wherein the second runout sensor is mounted on a second sensor advancing unit and can be advanced by this toward the rotor in the second direction.

10. Measuring device according to claim 8, wherein a second controller which uses the second runout sensor as a spacing sensor during the advancement of the same toward the rotor is provided for activating the second sensor advancing unit.

11. Measuring device according to claim 10, wherein the controller advances the second runout sensor with the rotor rotating.

12. Measuring device for electric motors, in particular spindle motors, comprising a motor mount, in which the electric motor to be tested can be positioned on the stator side for the measurement, and a first runout measuring device, which has at least a first runout sensor and with which a runout in a first direction can be sensed on a rotor of the electric motor held in the motor mount, the runout measuring device determining for every individual revolution from a multiplicity of revolutions of the rotor in the same rotational positions of the rotor in each case a measured value associated with each individual rotational position for the runout.

13. Measuring device according to claim 12, wherein the ascertainment of the individual rotational positions is performed by synchronization of a trigger signal for the runout measurement by the respective runout measuring device with the rotational movement of the rotor.

14. Measuring device according to claim 13, wherein the synchronization of the runout measurement with the rotational movement of the rotor is performed by the respective runout measuring device without any markings.

15. Measuring device according to claim 14, wherein the synchronization of the runout measurement with the rotational movement of the rotor is performed by sensing the variation over time of the voltage at an electrical terminal of the electric motor by means of a voltage sensing circuit.

16. Measuring device according to claim 15, wherein the voltage sensing circuit senses zero crossings of the voltage at the one electrical terminal of the electric motor.

17. Measuring device according to claim 16, wherein, after sensing a zero crossing, the voltage sensing circuit senses the zero crossing corresponding to the number of poles of the electric motor and indicating the beginning of the next-following revolution.

18. Measuring device according to claim 17, wherein the sensing of the zero crossings respectively indicating a new revolution is used in a phase-locked manner to derive a corresponding trigger signal, by which a subdivision of each revolution of the rotor takes place into a defined number of rotational positions for which a measured value of the respective runout sensor is to be sensed.

19. Measuring device according claim 12, wherein a measured-value acquisition, which acquires the measured values for each individual rotational position that are measured by the respective runout sensor, is provided.

20. Measuring device according to claim 19, wherein the measured-value acquisition forms a mean value from the measured values of the respective runout sensor that are associated with each individual rotational position.

21. Measuring device according to claim 20, wherein the measured-value acquisition determines the maximum difference between the mean values of all the rotational positions of a revolution of the rotor.

22. Measuring device according to claim 20, wherein the measured-value acquisition determines the maximum deviation of the measured values from the mean value for each rotational position.

23. Measuring device according to claim 22, wherein the measured-value acquisition determines the maximum difference between the maximum deviations ascertained in respect of all the rotational positions of a revolution of the rotor.

24. Measuring device according to claim 1, wherein the time-dependently ascertained measured values for the runout are Fourier-transformed by a computer and in that a frequency spectrum resulting from this is evaluated.

25. Measuring device according to claim 24, wherein an analysis of the frequency spectrum corresponding to all the speed-harmonic frequencies is performed.

26. Measuring device for electric motors, in particular spindle motors, comprising a motor mount, in which the electric motor to be tested can be positioned on the stator side for the measurement, a voltage induction measuring device, which measures a voltage induced in the non-energized windings of the electric motor with the rotor running freely.

27. Measuring device according to claim 26, wherein the voltage induction measuring device is connected to the windings via a switching unit and in that the switching unit can be switched in such a way that the induced voltage can be measured directly after energizing of the electric motor is switched off.

28. Measuring device according to claim 27, wherein the measuring device ascertains by means of a computer the amplitude maxima and zero crossings of the induced voltage influenced by reducing the rotational speed of the rotor, and adapts a theoretical profile of the induced voltage to these values and uses this adapted theoretical profile to ascertain the amplitude values of the induced voltage and zero crossings for an unbraked rotation of the rotor.

29. Measuring device according to claim 28, wherein the computer senses the variation over time of the amplitude of the induced voltage by means of an envelope curve adapted to amplitude maxima of the induced voltage.

30. Measuring device according to claim 26, wherein the measuring device has an inductance measuring device and an external stepping motor for driving the rotor, in that the stepping motor can be used to rotate the rotor into individual rotational positions and in that the inductance measuring device can be connected to the winding terminals of the electric motor, so that a measured value of the inductance of windings of the electric motor can be sensed in respect of each rotational position.

31. Measuring device according to claim 26, wherein the measuring device has a stray flux measuring device comprising a stray flux sensor and in that, in a measuring position with the rotor slowing down and without energizing of the same, the stray flux sensor measures a minimum value and a maximum value of the magnetic stray flux at a specifiable location of the rotor.

32. Measuring device according to claim 26, wherein the measuring device comprises a winding resistance measuring device, which measures the resistance of the windings of the stationary electric motor.

33. Measuring method for electric motors, in particular spindle motors, in which the electric motor to be tested is positioned for the measurement on the stator side in a motor mount, a first runout measuring device, having a first runout sensor, is used to sense a runout of a rotor of the electric motor in a first direction, and a second runout measuring device, having a second runout sensor, is used to sense a runout of the rotor in a second direction, extending transversely in relation to the first direction, at the same time as the runout in the first direction.

34. Measuring method according to claim 33, wherein the first runout sensor and the second runout sensor operate with a phase shift.

35. Measuring method according to claim 34, wherein the first runout sensor and the second runout sensor operate approximately in phase opposition.

36. Measuring method according to claim 33, wherein the first runout sensor is used as a spacing sensor during the advancement of the same toward the rotor.

37. Measuring method according to claim 33, wherein the second runout sensor is used as a spacing sensor during the advancement of the same toward the rotor.

38. Measuring method for electric motors, in particular spindle motors, in which the electric motor to be tested is positioned for the measurement on the stator side in a motor mount, a first runout measuring device, having a first runout sensor, is used to sense a runout of a rotor of the electric motor in a first direction, and for every individual revolution from a multiplicity of revolutions of the rotor in the same rotational positions of the rotor, in each case a measured value associated with each individual rotational position is determined for the runout.

39. Measuring method according to claim 38, wherein the individual rotational positions are ascertained by synchronization of a trigger signal for the runout measurement with the rotational movement of the rotor.

40. Measuring method according to claim 39, wherein the synchronization of the runout measurement with the rotational movement of the rotor is carried out without any markings.

41. Measuring method according to claim 40, wherein the synchronization of the runout measurement with the rotational movement of the rotor is carried out by sensing the variation over time of the voltage at an electrical terminal of the electric motor.

42. Measuring method according to claim 41, wherein, for the synchronization, zero crossings of the voltage are sensed at the one electrical terminal of the electric motor.

43. Measuring method according to claim 42, wherein, after sensing a zero crossing, the zero crossing corresponding to the number of poles of the electric motor and indicating the beginning of the next-following revolution is ascertained.

44. Measuring method according to claim 43, wherein the sensing of the zero crossings respectively indicating a new revolution is used in a phase-locked manner to derive a corresponding trigger signal, by which a subdivision of each revolution of the rotor is carried out into a defined number of rotational positions for which a measured value of the respective runout sensor is sensed.

45. Measuring method according to claim 44, wherein a mean value is formed from the measured values of the respective runout sensor that are associated with each individual rotational position.

46. Measuring method according to claim 45, wherein the maximum difference between the mean values of all the rotational positions of a revolution of the rotor is determined.

47. Measuring method according to claim 46, wherein the maximum deviation of the measured values from the mean value is determined for each rotational position.

48. Measuring method according to claim 47, wherein the maximum difference between the maximum deviations ascertained in respect of all the rotational positions of a revolution of the rotor is determined.

49. Measuring method according to claim 38, wherein the time-dependently ascertained measured values for the runout are Fourier-transformed by a computer and in that a frequency spectrum resulting from this is evaluated.

50. Measuring method according to claim 49, wherein an analysis of the frequency spectrum with regard to all the speed-harmonic frequencies is carried out.

51. Measuring method for electric motors, in particular spindle motors, in which the electric motor to be tested is positioned for the measurement on the stator side in a motor mount, and a voltage induced in the non-energized windings of the electric motor with the rotor running freely is measured.

52. Measuring method according to claim 51, wherein the amplitude maxima and zero crossings of the induced voltage influenced by reducing the rotational speed of the rotor are ascertained, and a theoretical profile of the induced voltage is adapted to these values and this adapted theoretical profile is used to ascertain the amplitude values of the induced voltage and zero crossings for an unbraked rotation of the rotor.

53. Measuring method according to claim 52, wherein the variation over time of the amplitude of the induced voltage by means of an envelope curve adapted to amplitude maxima of the induced voltage is sensed.

54. Measuring method according to claim 51, wherein a measured value of the inductance of windings of the electric motor is sensed in respect of each rotational position of the rotor.

55. Measuring method according to claim 51, wherein, in a measuring position with the rotor slowing down and without energizing of the same, a minimum value and a maximum value of the magnetic stray flux at a specifiable location of the rotor is measured.

56. Measuring method according to claim 51, wherein the resistance of the windings of the stationary electric motor is measured.

57. Measuring method according to claim 51, wherein a current fed to the windings with the electric motor running is measured.
